(19) United States
(12) Patent Application Publication
(10) Pub. No.: US 2014/0057414 A1
(43) Pub. Date: Feb. 27, 2014

(54) MASK RESIDUE REMOVAL FOR SUBSTRATE DICING BY LASER AND PLASMA ETCH

(71) Applicants: Aparna IYER, Sunnyvale, CA (US); Wei-Sheng LEI, San Jose, CA (US); Brad EATON, Menlo Park, CA (US); Ajay KUMAR, Cupertino, CA (US)

(72) Inventors: Aparna IYER, Sunnyvale, CA (US); Wei-Sheng LEI, San Jose, CA (US); Brad EATON, Menlo Park, CA (US); Ajay KUMAR, Cupertino, CA (US)

(21) Appl. No.: 13/973,642

(22) Filed: Aug. 22, 2013

Related U.S. Application Data
(60) Provisional application No. 61/693,673, filed on Aug. 27, 2012.
(60) Provisional application No. 61/790,910, filed on Mar. 15, 2013.

(51) Int. Cl. H01L 21/78; B23K 26/38

(52) U.S. Cl. CPC H01L 21/78; B23K 26/38
USPC 438/463; 219/121.67

(57) ABSTRACT

Methods of dicing substrates having a plurality of ICs. A method includes forming a mask and patterning the mask with a femtosecond laser scribing process to provide a patterned mask with gaps. The patterning exposes regions of the substrate between the ICs. The substrate is etched through the gaps in the patterned mask to singulate the IC. The mask is removed and metallized bumps on the diced substrate are contacted with an inorganic acid solution to remove mask residues.

### CROSS REFERENCE TO RELATED APPLICATIONS

This application claims the benefit of priority to U.S. Provisional Application No. 61/693,673 filed on Aug. 27, 2012, titled “MASK RESIDUE REMOVAL FOR SUBSTRATE DICING BY LASER AND PLASMA ETCH,” and U.S. Provisional Application No. 61/790,910 filed on Mar. 15, 2013, titled “MASK RESIDUE REMOVAL FOR SUBSTRATE DICING BY LASER AND PLASMA ETCH,” the entire contents of which are hereby incorporated by reference in its entirety for all purposes.

### TECHNICAL FIELD

Embodiments of the present invention pertain to the field of semiconductor processing and, in particular, to masking methods for dicing substrates, each substrate having an integrated circuit (IC) thereon.

### BACKGROUND DESCRIPTION OF RELATED ART

In semiconductor substrate processing, integrated circuits (ICs) are formed on a substrate (also referred to as a wafer), typically composed of silicon or other semiconductor material. In general, thin film layers of various materials which are either semiconducting, conducting, or insulating are utilized to form the ICs. These materials are doped, deposited, and etched using various well-known processes to simultaneously form a plurality of ICs, such as memory devices, logic devices, photovoltaic devices, etc., in parallel on a same substrate.

Following device formation, the substrate is mounted on a supporting member such as an adhesive film stretched across a film frame and the substrate is “diced” to separate each individual device or “die” from one another for packaging, etc. Currently, the two most popular dicing techniques are scribing and sawing. For scribing, a diamond tipped scribe is moved across a substrate surface along pre-formed scribe lines. Upon the application of pressure, such as with a roller, the substrate separates along the scribe lines. For sawing, a diamond tipped saw cuts the substrate along the streets. For thin substrate singulation, such as 50-150 μm thick bulk silicon singulation, the conventional approaches have yielded only poor process quality. Some of the challenges that may be faced when singulating dies from thin substrates may include microcrack formation or delamination between different layers, chipping of inorganic dielectric layers, retention of strict kerf width control, or precise ablation depth control.

While plasma dicing has also been contemplated, a standard lithography operation for patterning resist may render implementation cost prohibitive. Another limitation possibly hampering implementation of plasma dicing is that plasma processing of commonly encountered metals (e.g., copper) in dicing along streets can create production issues or throughput limits. Finally, masking of the plasma dicing process may be problematic, depending on, for example, the thickness and top surface topography of the substrate, the selectivity of the plasma etch, and the materials present on the top surface of the substrate. As such, the masking materials selected may be problematic to remove once die singulation has been performed.

### SUMMARY

One or more embodiments of the invention are directed to methods of dicing a substrate comprising a plurality of integrated circuits (ICs). In one embodiment, the method involves forming a mask over the substrate covering and protecting the ICs. The method involves patterning the mask with a laser scribing process to provide a patterned mask with gaps, exposing regions of the substrate between the ICs. The method involves plasma etching the substrate through the gaps in the patterned mask to singulate the ICs. The method further involves removing the mask, and exposing metal bumps or pads on a surface of the diced substrate to an inorganic acid solution.

In one embodiment, a system for dicing a substrate having a plurality of ICs includes a laser scribe module to pattern a mask and expose regions of the substrate between the ICs, the ICs including metal bumps or pads. The system includes a plasma etch module physically coupled to the laser scribe module to plasma etch the substrate to singulate the ICs. The system includes a wet clean station coupled to the plasma etch module, the wet clean station configured to remove the mask and to perform an inorganic acid wash of the exposed metal bumps or pads. The system further includes a robotic transfer chamber to transfer a laser scribed substrate from the laser scribe module to the plasma etch module and from the plasma etch module to the wet clean station.

### BRIEF DESCRIPTION OF THE DRAWINGS

Embodiments of the present invention are illustrated by way of example, and not limitation, in the figures of the accompanying drawings in which:

FIG. 1 is a flow diagram illustrating a hybrid laser ablation-plasma etch singulation method, in accordance with an embodiment of the present invention;

FIG. 2A illustrates a cross-sectional view of a semiconductor substrate including a plurality of ICs corresponding to operation 102 of the dicing method illustrated in FIG. 1, in accordance with an embodiment of the present invention;

FIG. 2B illustrates a cross-sectional view of a semiconductor substrate including a plurality of ICs corresponding to operation 103 of the dicing method illustrated in FIG. 1, in accordance with an embodiment of the present invention;

FIG. 2C illustrates a cross-sectional view of a semiconductor substrate including a plurality of ICs corresponding to operation 105 of the dicing method illustrated in FIG. 1, in accordance with an embodiment of the present invention; and

FIG. 2D illustrates a cross-sectional view of a semiconductor substrate including a plurality of ICs corresponding to operation 107 of the dicing method illustrated in FIG. 1, in accordance with an embodiment of the present invention;

FIG. 3A illustrates a cross-sectional view of a water soluble mask applied over a top surface and subsurface thin films of a substrate including a plurality of ICs, in accordance with embodiments of the present invention;

FIG. 3B illustrates a cross-sectional view of a multi-layered mask applied over a top surface and subsurface thin films of a substrate including a plurality of ICs, in accordance with embodiments of the present invention;

FIG. 4 illustrates a plan view schematic of an integrated dicing system in accordance with an embodiment of the present invention; and

FIG. 5 illustrates a block diagram of an exemplary computer system which controls automated performance of one or more operation in the masking, laser scribing, plasma dicing methods described herein, in accordance with an embodiment of the present invention.

### DETAILED DESCRIPTION

Methods of dicing substrates, each substrate having a plurality of ICs thereon, are described. In the following description, numerous specific details are set forth, such as femtosecond laser scribing and deep silicon plasma etching conditions in order to describe exemplary embodiments of the present invention. However, it will be apparent to one skilled in the art that embodiments of the present invention may be practiced without these specific details. In other instances, well-known aspects, such as IC fabrication, substrate thinning, taping, etc., are not described in detail to avoid unnecessarily obscuring embodiments of the present invention. Reference throughout this specification to “an embodiment” means that a particular feature, structure, material, or characteristic described in connection with the embodiment is included in at least one embodiment of the invention. Thus, the appearances of the phrase “in an embodiment” in various places throughout this specification are not necessarily referring to the same embodiment of the invention. Furthermore, the particular features, structures, materials, or characteristics may be combined in any suitable manner in one or more embodiments. Also, it is to be understood that the various exemplary embodiments shown in the Figures are merely illustrative representations and are not necessarily drawn to scale.

The terms “coupled” and “connected,” along with their derivatives, may be used herein to describe structural relationships between components. It should be understood that these terms are not intended as synonyms for each other. Rather, in particular embodiments, “connected” may be used to indicate that two or more elements are in direct physical or electrical contact with each other. “Coupled” my be used to indicate that two or more elements are in either direct or indirect (with other intervening elements between them) physical or electrical contact with each other, and/or that the two or more elements co-operate or interact with each other (e.g., as in a cause an effect relationship).

The terms “over,” “under,” “between,” and “on” as used herein refer to a relative position of one material layer with respect to other material layers. As such, for example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in contact with that second layer. Additionally, the relative position of one layer with respect to other layers is provided assuming operations are performed relative to a substrate without consideration of the absolute orientation of the substrate.

Generally, a hybrid substrate or substrate dicing process involving an initial laser scribe and subsequent plasma etch is implemented with a mask for die singulation. The laser scribe process may be used to cleanly remove an unpatterned (i.e., blanket) mask layer, passivation layer, and subsurface thin film device layers. The laser etch process may then be terminated upon exposure of, or partial ablation of, the substrate. The plasma etch portion of the hybrid dicing process may then be employed to etch through the bulk of the substrate, such as through bulk single crystalline silicon, for singulation or dicing of chips.

In accordance with an embodiment of the present invention, a combination of femtosecond laser scribing and plasma etching is used to dice a semiconductor substrate into individualized or singulated ICs. In one embodiment, femtosecond laser scribing is an essentially, if not completely, non-equilibrium process. For example, the femtosecond-based laser scribing may be localized with a negligible thermal damage zone. In an embodiment, laser scribing is used to singulate ICs having ultra-low κ films (i.e., with a dielectric constant below 3.0). In one embodiment, direct writing with a laser eliminates a lithography patterning operation, allowing the masking material to be non-photosensitive, and plasma etch-based dicing processing is implemented with very little cost to partition the substrate. In one embodiment, through silicon via (TSV)-type etching is used to complete the dicing process in a plasma etch chamber.

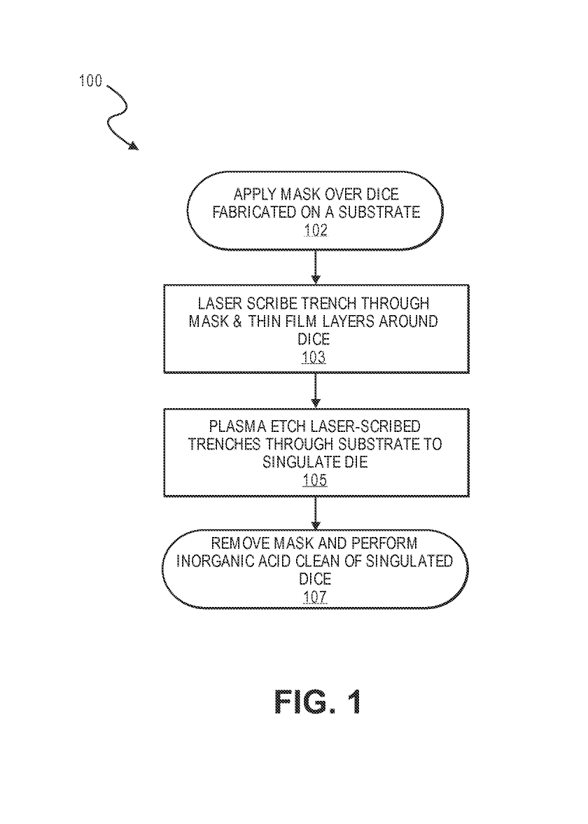

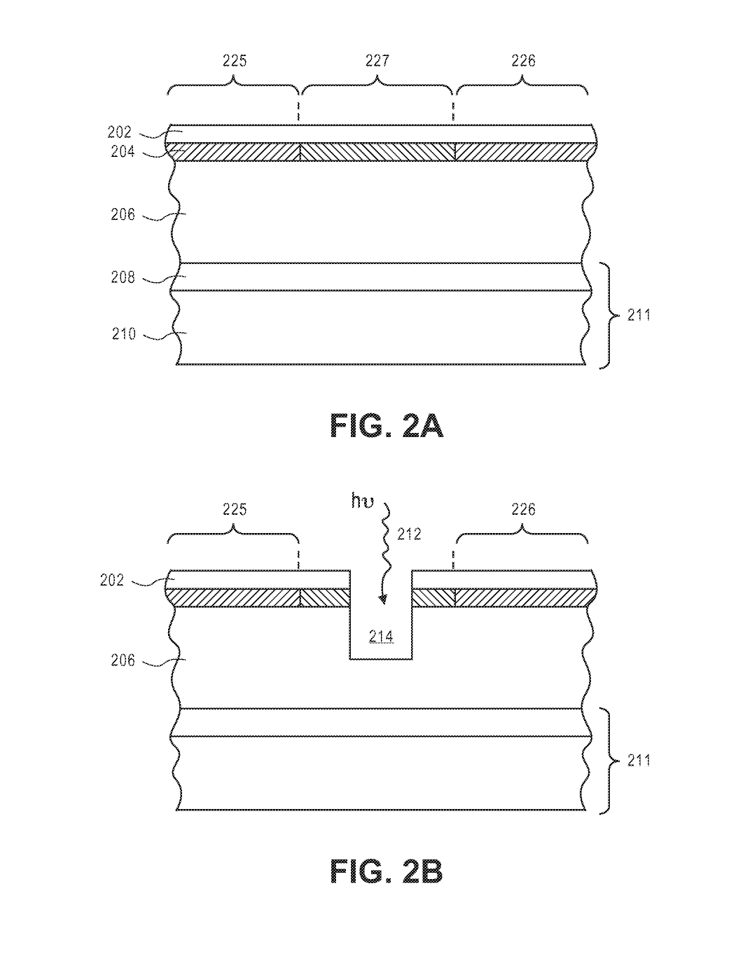

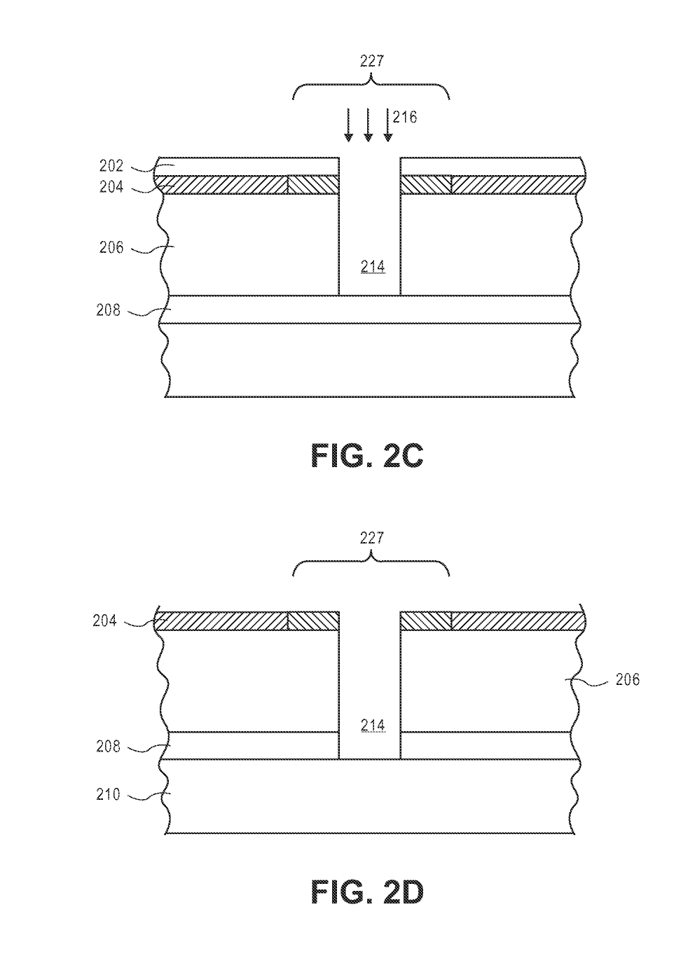

FIG. 1 is a flow diagram illustrating a hybrid laser ablation-plasma etch singulation process 100, in accordance with an embodiment of the present invention. FIGS. 2A-2D illustrate cross-sectional views of a substrate 206 including first and second ICs 225, 226, and correspond to the operations in method 100, in accordance with an embodiment of the present invention.

Referring to operation 102 of FIG. 1, and corresponding FIG. 2A, a mask layer 202 is formed above the substrate 206. Generally, the substrate 206 is composed of any material suitable to withstand a fabrication process of the thin film device layers 204 formed thereon. For example, in one embodiment, the substrate 206 is a group IV-based material such as, but not limited to, monocrystalline silicon, germanium or silicon/germanium. In another embodiment, the substrate 206 is a III-V material such as, e.g., a III-V material substrate used in the fabrication of light emitting diodes (LEDs). During device fabrication, the substrate 206 is typically 600 μm to 800 μm thick, but as illustrated in FIG. 2A has been thinned to 50 μm to 100 μm. In one embodiment, the thinned substrate is supported by a carrier or backside support 211, such as a backing tape 210 stretched across a frame (not illustrated) and adhered to a backside of the substrate 206 with a die attach film (DAF) 208.

In embodiments, first and second ICs 225, 226 include memory devices or complimentary metal-oxide-semiconductor (CMOS) transistors fabricated in a silicon substrate 206 and encased in a dielectric stack. A plurality of metal interconnects may be formed above the devices or transistors, and in surrounding dielectric layers, and may be used to electrically couple the devices or transistors to form the ICs 225, 226. Materials making up the street 227 may be similar to or the same as those materials used to form the ICs 225, 226. For example, street 227 may include thin film layers of dielectric materials, semiconductor materials, and metallization. In one embodiment, the street 227 includes a test device similar to the ICs 225, 226. The width of the street 227 may be anywhere between 10 μm and 100 μm.

In embodiments, the mask layer 202 includes a water soluble material layer covering a top surface of the ICs 225, 226. The mask layer 202 also covers the intervening street 227 between the ICs 225, 226. The water soluble material layer is to provide protection of a top surface of the ICs 225, 226 during the hybrid laser scribing and plasma etch dicing method 100 of FIG. 1. The mask layer 202 is unpatterned prior to the laser scribing operation 103. The scribing laser is to perform a direct writing of the scribe lines by ablating portions of the mask layer 202 disposed over the street 227.

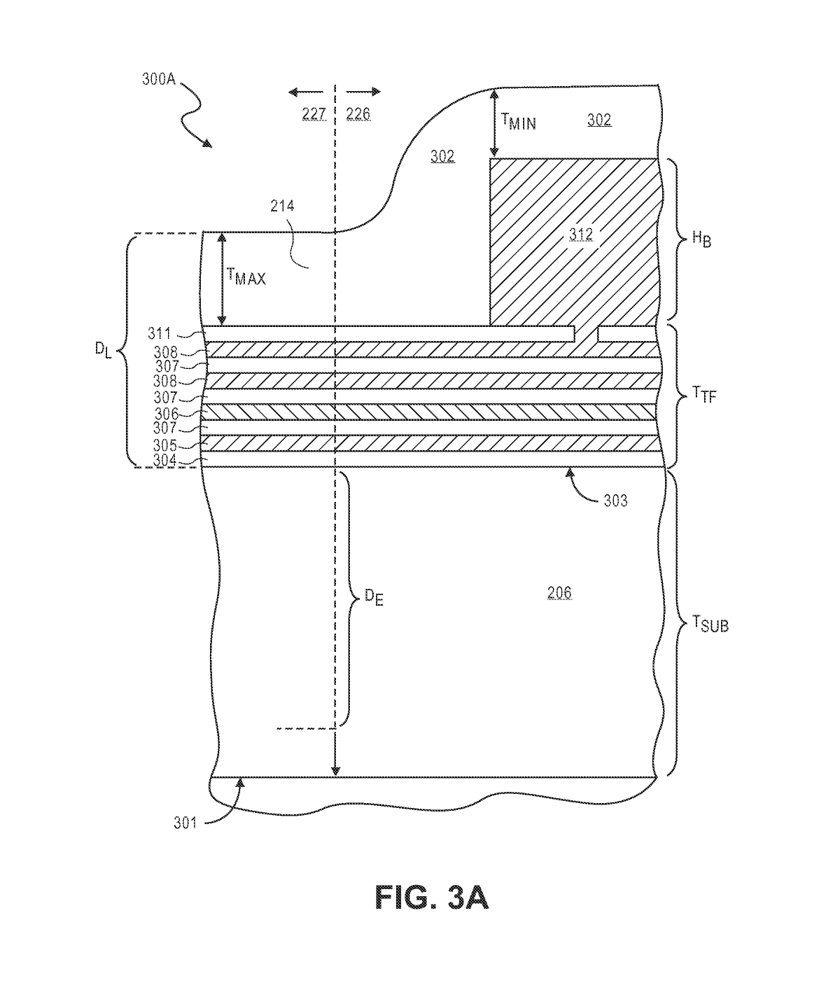

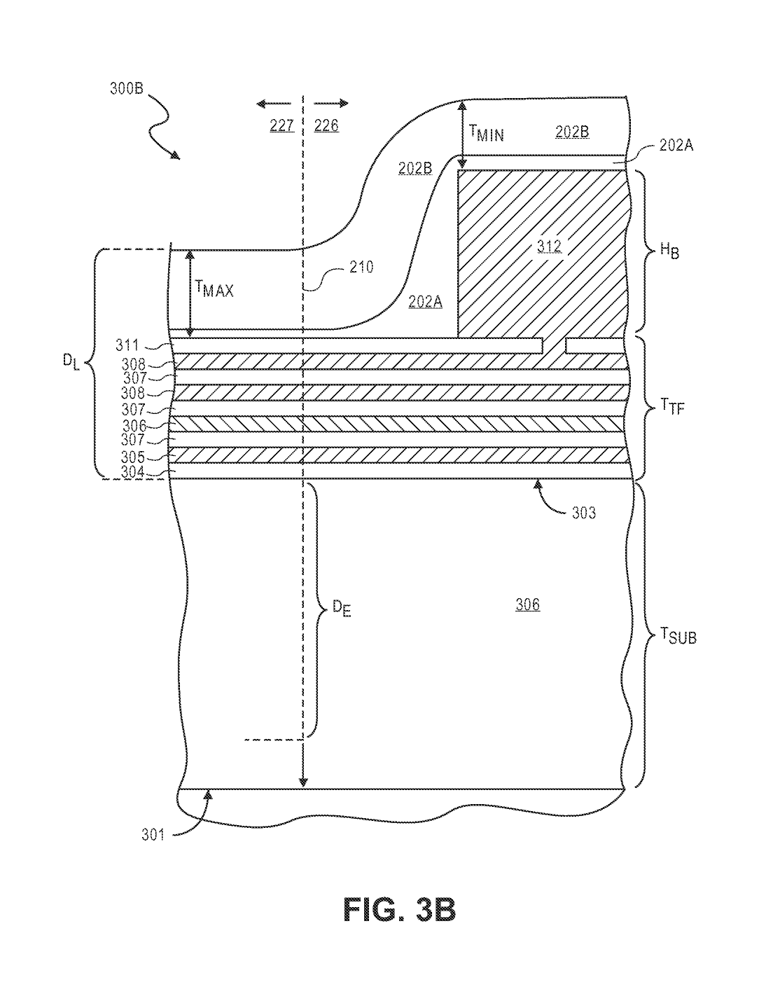

FIG. 3A illustrates an expanded cross-sectional view 300A of one exemplary embodiment including a water soluble layer 302 in contact with a top surface of the IC 226 and the street 227, in accordance with embodiments of the present invention. As shown in FIG. 3A, the substrate 206 has a top surface 303 upon which thin film device layers are disposed, which is opposite a bottom surface 301 which interfaces with the DAF 208 of FIG. 2A. Generally, the thin film device layer materials may include, but are not limited to, organic materials (e.g., polymers), metals, or inorganic dielectrics such as silicon dioxide and silicon nitride. The exemplary thin film device layers illustrated in FIG. 3A include a silicon dioxide layer 304, a silicon nitride layer 305, copper interconnect layers 308 with low-κ (e.g., less than 3.5) or ultra low-κ (e.g., less than 3.0) interlayer dielectric layers (ILD) 307 such as carbon doped oxide (CDO) disposed there between. A top surface of the IC 226 includes a bump 312, typically copper, surrounded by a passivation layer 311, typically a polyimide (PI) or similar polymer. The bumps 312 and passivation layer 311 therefore make up a top surface of the IC with the thin film device layers forming subsurface IC layers. The bump 312 extends from a top surface of the passivation layer 311 by a bump height H_{B} which, in the exemplary embodiments, ranges between 10 μm and 50 μm.

In an embodiment, the water soluble layer 302 is the mask layer 202, such that the mask layer 202 includes no other material layers. In other embodiments the water soluble layer 302 is only a first (bottom) layer of a multi-layered mask stack, as shown in FIG. 3B. Unlike other more conventional masking materials such as photoresist, or inorganic dielectric hardmasks such as silicon dioxide, or silsesquioxanes, a mask including the water soluble layer 302 may be readily removed without damage to the underlying passivation layer 311 and/or bump 312. Where the water soluble layer 302 is the mask layer 202, the water soluble layer 302 is more than a mere contamination protection layer utilized during a conventional scribing process, and is instead to provide protection during the subsequent plasma etching of the streets, according to an embodiment. As such, the water soluble layer 302 is to be of sufficient thickness to survive the plasma etch process, protecting even the bump 312 which, being copper, may be damaged, oxidized, or otherwise contaminated if exposed to the plasma. The minimum thickness of the water soluble layer 302 is a function of the selectivity achieved by the subsequent plasma etch (e.g., operation 105 in FIG. 1). The plasma etch selectivity is dependent on at least the material/composition of the water soluble layer 302 and the etch process employed.

In an embodiment, the water soluble material comprises a water soluble polymer. Many such polymers are commercially available for applications such as laundry and shopping bags, embroidery, green packaging, etc. However, selection of water soluble material for the present invention is complicated by stringent demands on maximum film thickness, etch resistance, thermal stability, mechanics of applying and removing the material from the substrate, and microcontamination. In the street, the maximum thickness Tₘₐₓ of the water soluble layer 302 is limited by the ability of a laser to pattern through the masking by ablation. The water soluble layer 302 may be much thicker over the ICs 225, 226 and or edges of the street 227 where no street pattern is to be formed. As such, Tₘₐₓ is generally a function of the optical conversion efficiency associated with laser wavelength. As Tₘₐₓ is associated with the street 227, street feature topography, street width, and the method of applying the water soluble layer 302 may be selected to achieve a desired Tₘₐₓ. In particular embodiments, the water soluble layer 302 has a thickness Tₘₐₓ which is less than 30 μm and advantageously less than 20 μm with a thicker mask calling for multiple laser passes.

In an embodiment, the water soluble layer 302 is thermally stable to at least 60° C., preferably stable at 100° C., and ideally stable to 120° C. to avoid excessive crosslinking during the subsequent plasma etch process when the material's temperature will be elevated. Generally, excessive crosslinking adversely affects the solubility of the material, making post-etch removal more difficult. Depending on the embodiment, the water soluble layer 302 may be either wet applied onto the substrate 206 to cover the passivation layer 311 and bump 312 or applied as a dry film laminate. For either mode of application, exemplary materials include, at least one of: poly(vinyl alcohol), poly(acrylic acid), poly(methacrylic acid), poly(acrylamide), or poly(ethylene oxide) with many other water soluble materials also readily available, particularly as a dry film laminate. Dry films for lamination may include the water soluble material only or may further include an adhesive layer that may also be water soluble or not. In a particular embodiment, the dry film includes a UV sensitive adhesive layer which has reduced adhesive bond strength upon UV exposure. Such UV exposure may occur during the subsequent plasma street etch.

Experimentally, poly(vinyl alcohol) (PVA) has been found to provide an etch rate of between 1 μm/min and 1.5 μm/min for the exemplary silicon plasma etch processes described elsewhere herein for an etch rate selectivity of approximately 1:20 (PVA:silicon). The other exemplary materials may offer similar etch performance. As such, the minimum thickness over a top bump surface of an IC (e.g., Tₘᵢₙ in FIGS. 3A and 3B) may be determined by the plasma etch depth D_{E} which is both a function of the thickness of the substrate T_{Sub} and laser scribe depth D_{L}. In the exemplary embodiment where D_{E} is at least 50 μm, the water soluble layer 302 has a thickness of at least 5 μm and advantageously at least 10 μm to provide sufficient margin for D_{E} of at least 100 μm.

FIG. 3B illustrates an expanded cross-sectional view 300B of one exemplary embodiment including a multi-layered mask including a laser energy absorbing material layer 202B disposed over a water-soluble layer 202A that is in contact with a top surface of the IC 226 and the street 227. In embodiments with multiple mask layers, the water-soluble base coat is disposed below a non-water-soluble overcoat. The basecoat then provides a means of stripping the overcoat while the overcoat provides plasma etch resistance and/or for good mask ablation by the laser scribing process. It has been found for example, that mask materials transparent to the laser wavelength employed in the scribing process contribute to low die edge strength. Hence, a water-soluble base coat, of PVA, for example, as the first mask material layer 202A, may function as a means of undercutting a plasma-resistant/laser energy absorbing overcoat layer 202B of the mask so that the entire mask may be removed/lifted off from the underlying IC thin film layer. The water-soluble base coat may further serve as a barrier protecting the IC thin film layer from the process used to strip the energy absorbing mask layer. In embodiments, the laser energy absorbing mask layer is UV-curable and/or UV absorbing, and/or green-band (500-540 nm) absorbing. Exemplary materials include many photo-resists and polyimide (PI) materials conventionally employed for passivation layers of IC chips, as well as UV curable polymers often found in adhesives. In one embodiment, the photo-resist layer is composed of a positive photo-resist material such as, but not limited to, a 248 nanometer (nm) resist, a 193 nm resist, a 157 nm resist, an extreme ultra-violet (EUV) resist, or a phenolic resin matrix with a diazonaphthoquinone sensitizer. In another embodiment, the photo-resist layer is composed of a negative photo-resist material such as, but not limited to, poly-cis-isoprene and poly-vinyl-cinnamate.

At operation 103 of method 100, and corresponding FIG. 2B, the mask layer 202 is patterned by ablation with a laser scribing process forming trenches 212, extending through the subsurface thin film device layers 204, and exposing regions of the substrate 206 between the ICs 225, 226. As such, the laser scribing process is used to ablate the thin film material of the streets 227 originally formed between the ICs 225, 226. In accordance with an embodiment of the present invention, patterning the mask layer 202 with the laser-based scribing process includes forming trenches 214 partially into the regions of the substrate 206 between the ICs 225, 226, as depicted in FIG. 2B.

In the exemplary embodiment illustrated in FIG. 3A, the laser scribing depth D_{L} is approximately in the range of 5 μm to 50 μm deep, advantageously in the range of 10 μm to 20 μm deep, depending on the thickness T_{F} of the passivation layer 311 and subsurface thin film device layers and thickness Tₘₐₓ of the water soluble layer 302 (and any additional material layer included as part of the mask 202).

In an embodiment, the mask layer 202 is patterned with a laser having a pulse width (duration) in the femtosecond range (i.e., 10⁻¹⁵ seconds), referred to herein as a femtosecond laser. According to one embodiment, patterning the mask includes direct writing a pattern with a femtosecond laser having a wavelength less than or equal to 540 nanometers and a laser pulse width less than or equal to 400 femtoseconds. In another embodiment, the laser pulse width is less than or equal to 500 femtoseconds. Laser parameters selection, such as pulse width, may be critical to developing a successful laser scribing and dicing process that minimizes chipping, microcracks and delamination in order to achieve clean laser scribe cuts. A laser frequency in the femtosecond range advantageously mitigates heat damage issues relative to longer pulse widths (e.g., picosecond or nanosecond). Although not bound by theory, as currently understood a femtosecond energy source avoids low energy recoupling mechanisms present for picosecond sources and provides for greater thermal nonequilibrium than does a nanosecond-source. With nanosecond or picosecond laser sources, the various thin film device layer materials present in the street 227 behave quite differently in terms of optical absorption and ablation mechanisms. For example, dielectric layers such as silicon dioxide, are essentially transparent to all commercially available laser wavelengths under normal conditions. By contrast, metals, organics (e.g., low-κ materials) and silicon can couple photons very easily, particularly nanosecond-based or picosecond-based laser irradiation. If non-optimal laser parameters are selected, in stacked structures that include two or more of an inorganic dielectric, an organic dielectric, a semiconductor, or a metal, laser irradiation of the street 227 may disadvantageously cause delamination. For example, a laser penetrating through high bandgap energy dielectrics (such as silicon dioxide with an approximately 9 eV bandgap) without measurable absorption may be absorbed in an underlying metal or silicon layer, causing significant vaporization of the metal or silicon layers. The vaporization may generate high pressures potentially causing severe interlayer delamination and microcracking. Femtosecond-based laser irradiation processes have been demonstrated to avoid or mitigate such microcracking or delamination of such material stacks.

Parameters for a femtosecond laser-based process may be selected to have substantially the same ablation characteristics for the inorganic and organic dielectrics, metals, and semiconductors. For example, the absorptivity/absorptance of silicon dioxide is non-linear and may be brought more in-line with that of organic dielectrics, semiconductors, and metals. In one embodiment, a high intensity and short pulse width femtosecond-based laser process is used to ablate a stack of thin film layers including a silicon dioxide layer and one or more of an organic dielectric, a semiconductor, or a metal. In accordance with an embodiment of the present invention, suitable femtosecond-based laser processes are characterized by a high peak intensity (irradiance) that usually leads to nonlinear interactions in various materials. In one such embodiment, the femtosecond laser sources have a pulse width approximately in the range of 10 femtoseconds to 450 femtoseconds, although preferably in the range of 50 femtoseconds to 500 femtoseconds.

In certain embodiments, the laser emission spans any combination of the visible spectrum (e.g., the green, 500-540 nm band), the ultra-violet (UV), and/or infra-red (IR) spectrums for a broad or narrow band optical emission spectrum. Even for femtosecond laser ablation, certain wavelengths may provide better performance than others. For example, in one embodiment, a femtosecond-based laser process having a wavelength closer to or in the UV range provides a cleaner ablation process than a femtosecond-based laser process having a wavelength closer to or in the IR range. In a specific embodiment, a femtosecond laser suitable for semiconductor substrate or substrate scribing is based on a laser having a wavelength of approximately less than or equal to 540 nanometers, although preferably in the range of 540 nanometers to 250 nanometers. In a particular embodiment, pulse widths are less than or equal to 500 femtoseconds for a laser having a wavelength less than or equal to 540 nanometers. However, in an alternative embodiment, dual laser wavelengths (e.g., a combination of an IR laser and a UV laser) are used.

In one embodiment, the laser and associated optical pathway provide a focal spot at the work surface approximately in the range of 3 μm to 15 μm, though advantageously in the range of 5 μm to 10 μm. The spatial beam profile at the work surface may be a single mode (Gaussian) or have a beam shaped top-hat profile. In an embodiment, the laser source has a pulse repetition rate approximately in the range of 300 kHz to 10 MHz, although preferably approximately in the range of 500 kHz to 5 MHz In an embodiment, the laser source delivers pulse energy at the work surface approximately in the range of 0.5 μJ to 100 μJ, although preferably approximately in the range of 1 μJ to 5 μJ. In an embodiment, the laser scribing process runs along a work piece surface at a speed approximately in the range of 500 mm/sec to 5 msec, although preferably approximately in the range of 600 mm/sec to 2 msec.

The scribing process may be run in a single pass only, or in multiple passes, but is advantageously no more than two passes. The laser may be applied either in a train of single pulses at a given pulse repetition rate or a train of pulse bursts. In an embodiment, the kerf width of the laser beam generated is approximately in the range of 2 μm to 15 μm, although in silicon substrate scribing/dicing preferably approximately in the range of 6 μm to 10 μm, as measured at a device/silicon interface.

Returning to FIGS. 1 and 2C, the substrate 206 is etched through the trenches 212 in the patterned mask layer 202 via a plasma etching process 216 to singulate the ICs 226 at operation 105. In accordance with an embodiment of the present invention, etching the substrate 206 includes etching the trenches 212 formed with the femtosecond-based laser scribing process to ultimately etch entirely through substrate 206, as depicted in FIG. 2C.

In an embodiment, etching the substrate 206 includes using a plasma etching process. In one embodiment, a through via etch process is used. For example, in a specific embodiment, the etch rate of the material of substrate 206 is greater than 25 μm per minute. A high-density plasma source operating at high powers may be used for the plasma etching operation 105. Exemplary powers range between 3 kW and 6 kW, or more.

In an exemplary embodiment, a deep silicon etch (i.e., such as a through silicon via (TSV) etch) is used to etch a single crystalline silicon substrate or substrate 206 at an etch rate greater than approximately 40% of conventional silicon etch rates while maintaining essentially precise profile control and virtually scallop-free sidewalls. Effects of the high power on the mask are controlled through application of cooling power via an electrostatic chuck (ESC) chilled to −10° C. to −15° C. to maintain the mask layer at a temperature below 100° C. and preferably between 70° C. and 80° C. throughout the duration of the plasma etch process. At such temperatures, water solubility of the mask is advantageously maintained.

In a specific embodiment, the plasma etch entails a plurality of protective polymer deposition cycles interleaved over time with a plurality of etch cycles. The duty cycle may vary with the exemplary duty cycle being approximately 1:1. For example, the etch process may have a deposition cycle with a duration of 250 ms-750 ms and an etch cycle of 250 ms-750 ms. Between the deposition and etch cycles, an etching process chemistry, employing for example SF₆ for the exemplary silicon etch embodiment, is alternated with a deposition process chemistry, employing a polymerizing CₓF_{y} gas such as, but not limited to, C₄F₆, CF₄, or C₄F₈. Gases such as CF₄ and CHF₃ may be employed for some applications involving the etching of complex material stacks on wafers, for example, wafers having a SiO₂ layer on the backside. Process pressures may further be alternated between etch and deposition cycles to favor each in the particular cycle, as known in the art.

At operation 107, method 100 is completed with removal of the mask layer 202, as is depicted in FIG. 2D. In an embodiment, the mask is first washed off with water, for example with a pressurized jet of de-ionized water or submergence in an ambient or heated water bath. Residue or discoloration may be present on copper bumps after a de-ionized water rinse, which may cause problems during the packaging and assembly of the dies after singulation by preventing good electrical contact in the device. In particularly advantageous embodiments, the residue or discoloration is removed by contacting the bumped wafer surface with an aqueous solution of an inorganic acid in various concentrations and temperatures for an amount of time to effectively clean off the residue (e.g., 30 seconds to 5 minutes). Such inorganic acids include, for example, hydrochloric acid, phosphoric acid, or a blend of the two acids, Specific embodiments which have been verified effective are provided below in Table 1:

TABLE 1

| Chemistry | Normality | Temperature | Duration |
|---|---|---|---|
| Hydrochloric acid | 0.2-0.6N | 25-40° C. | 3-5 minutes |
| (HCl) | | | |
| Phosphoric acid | 2-6N | 25-40° C. | 3-5 minutes |
| (H₃PO₄) | | | |
| Blend of HCl & | 0.2/2N-0.6/6N | 25-40° C. | 3-5 minutes |
| H₃PO₄ | | | |

In one embodiment, after cleaning the bumps with an inorganic acid solution, the semiconductor wafer is rinsed (e.g., with water) to clean off the acid residue. Thus, in one embodiment, the inorganic acid wash removes foreign chemicals such as Fluorine (even if the bump surface has no visible residue) introduced by a plasma etching process that employs, for example, SF₆ and C₄F₈, etc., and/or mask residue.

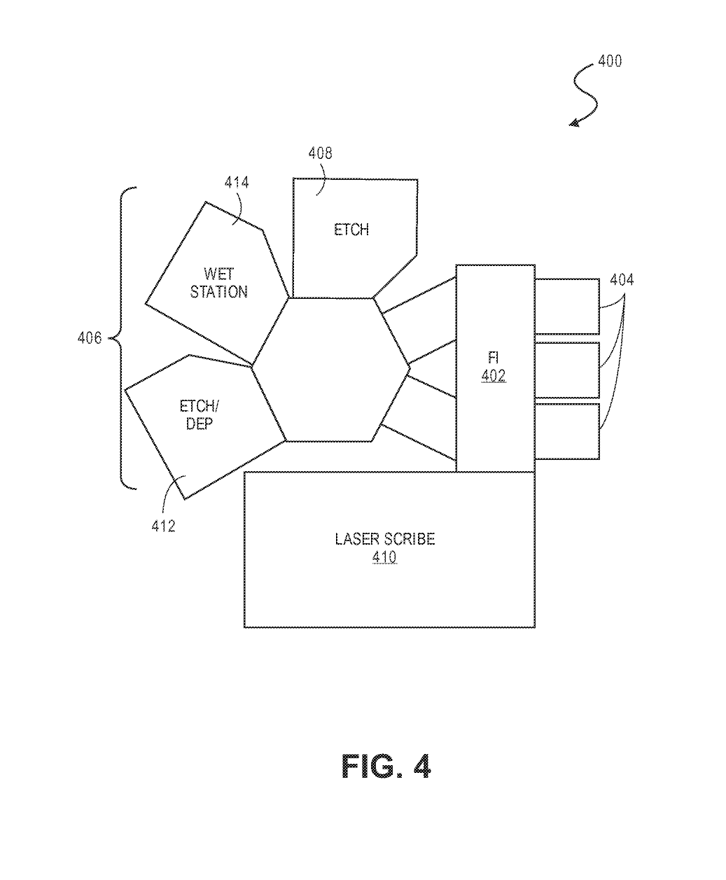

Turning to FIG. 4, a single integrated platform 400 may be configured to perform many or all of the operations in the hybrid laser ablation-plasma etch singulation process 100. For example, FIG. 4 illustrates a block diagram of a cluster tool 406 coupled with laser scribe apparatus 410 for laser and plasma dicing of substrates, in accordance with an embodiment of the present invention. The cluster tool 406 is coupled to a factory interface 402 (FI) having a plurality of load locks 404. The factory interface 402 may be a suitable atmospheric port to interface between an outside manufacturing facility with laser scribe apparatus 410 and cluster tool 406. The factory interface 402 may include robots with arms or blades for transferring substrates (or carriers thereof) from storage units (such as front opening unified pods) into either cluster tool 406 or laser scribe apparatus 410, or both.

A laser scribe apparatus 410 is also coupled to the FI 402. In an embodiment, the laser scribe apparatus 410 includes a femtosecond laser operating in the 300-540 nm band. The femtosecond laser to performing the laser ablation portion of the hybrid laser and etch singulation process 100. In one embodiment, a moveable stage is also included in laser scribe apparatus 410, the moveable stage configured for moving a substrate or wafer (or a carrier thereof) relative to the femtosecond-based laser. In a specific embodiment, the femtosecond laser is also moveable.

The cluster tool 406 includes one or more plasma etch chambers 408 coupled to the FI by a robotic transfer chamber housing a robotic arm for in-vaccuo transfer of substrates. The plasma etch chamber 408 is suitable for performing a plasma etch portion of the hybrid laser and etch singulation process 100. In one exemplary embodiment, the plasma etch chamber 408 is further coupled to an SF₆ gas source and at least one of a C₄F₈ and C₄F₆ source. In a specific embodiment, the one or more plasma etch chambers 408 is an Applied Centura® Silvia™ Etch system, available from Applied Materials of Sunnyvale, Calif., USA, although other suitable etch systems are also available commercially. In an embodiment, more than one etch chamber 408 is included in the cluster tool 406 portion of integrated platform 400 to enable high manufacturing throughput of the singulation or dicing process.

The cluster tool 406 may include other chambers suitable for performing functions in the hybrid laser ablation-plasma etch singulation process 100. In the exemplary embodiment illustrated in FIG. 4, the cluster tool 406 includes both a mask formation module 412 and a wet station 414, though either may be provided in absence of the other. The mask formation module 412 may be a spin coating module. As a spin coating module, a rotatable chuck is configured to clamp by vacuum, or otherwise, a thinned substrate mounted on a carrier such as backing tape mounted on a frame. In further embodiments, the spin coating module is fluidly coupled to an aqueous solution source.

Embodiments of the wet station 414 are to dissolve the water-soluble mask material layer after plasma etching the substrate. The wet station 414 may include for example a pressurized spray jet to dispense water or other solvent. In further embodiments, the wet station 414 includes an inorganic acid wash, for example, to expose a wafer to one or more of the inorganic acid cleanses described elsewhere herein.

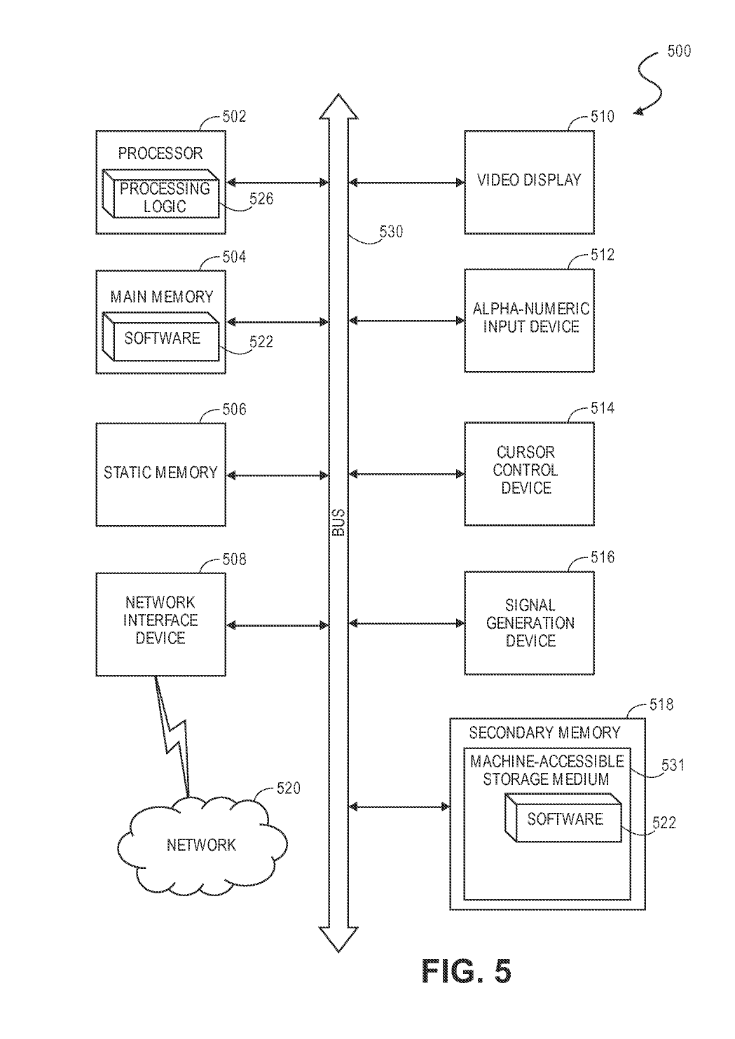

FIG. 5 illustrates a computer system 500 within which a set of instructions, for causing the machine to execute one or more of the scribing methods discussed herein may be executed. The exemplary computer system 500 includes a processor 502, a main memory 504 (e.g., read-only memory (ROM), flash memory, dynamic random access memory (DRAM) such as synchronous DRAM (SDRAM) or Rambus DRAM (RDRAM), etc.), a static memory 506 (e.g., flash memory, static random access memory (SRAM), etc.), and a secondary memory 518 (e.g., a data storage device), which communicate with each other via a bus 530.

Processor 502 represents one or more general-purpose processing devices such as a microprocessor, central processing unit, or the like. More particularly, the processor 502 may be a complex instruction set computing (CISC) microprocessor, reduced instruction set computing (RISC) microprocessor, very long instruction word (VLIW) microprocessor, etc. Processor 502 may also be one or more special-purpose processing devices such as an application specific integrated circuit (ASIC), a field programmable gate array (FPGA), a digital signal processor (DSP), network processor, or the like. Processor 502 is configured to execute the processing logic 526 for performing the operations and steps discussed herein.

The computer system 500 may further include a network interface device 508. The computer system 500 also may include a video display unit 510 (e.g., a liquid crystal display (LCD) or a cathode ray tube (CRT)), an alphanumeric input device 512 (e.g., a keyboard), a cursor control device 514 (e.g., a mouse), and a signal generation device 516 (e.g., a speaker).

The secondary memory 518 may include a machine-accessible storage medium (or more specifically a computer-readable storage medium) 531 on which is stored one or more sets of instructions (e.g., software 522) embodying any one or more of the methodologies or functions described herein. The software 522 may also reside, completely or at least partially, within the main memory 504 and/or within the processor 502 during execution thereof by the computer system 500, the main memory 504 and the processor 502 also constituting machine-readable storage media. The software 522 may further be transmitted or received over a network 520 via the network interface device 508.

While the machine-accessible storage medium 531 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies of the present invention. The term “machine-readable storage medium” shall accordingly be taken to include, but not be limited to, solid-state memories, optical and magnetic media, and other non-transitory media.

It is to be understood that the above description is intended to be illustrative, and not restrictive. For example, while flow diagrams in the figures show a particular order of operations performed by certain embodiments of the invention, it should be understood that such order is not required (e.g., alternative embodiments may perform the operations in a different order, combine certain operations, overlap certain operations, etc.). Furthermore, many other embodiments will be apparent to those of skill in the art upon reading and understanding the above description. Although the present invention has been described with reference to specific exemplary embodiments, it will be recognized that the invention is not limited to the embodiments described, but can be practiced with modification and alteration within the spirit and scope of the appended claims. The scope of the invention should, therefore, be determined with reference to the appended claims, along with the full scope of equivalents to which such claims are entitled.

What is claimed is:

1. A method of dicing a substrate comprising a plurality of integrated circuits (ICs), the method comprising:
forming a mask over the substrate covering and protecting the ICs;
patterning the mask with a laser scribing process to provide a patterned mask with gaps, exposing regions of the substrate between the ICs;
plasma etching the substrate through the gaps in the patterned mask to singulate the ICs;
removing the mask; and
exposing metal bumps or pads on a surface of the diced substrate to an inorganic acid solution.

2. The method of claim 1, wherein the inorganic acid solution comprises at least one of HCl and H₃PO₄.

3. The method of claim 2, wherein the inorganic acid solution comprises HCl with 0.2-0.6 normality at 25-40° C., and wherein the exposure occurs for a duration of 3-5 minutes.

4. The method of claim 2, wherein the inorganic acid solution comprises H₃PO₄ with 2-6 normality at 25-40° C., and wherein the exposure occurs for a duration of 3-5 minutes.

5. The method of claim 2, wherein the inorganic acid solution comprises a mixture of 0.2-0.6 normal HCl with 2-6 normal H₃PO₄ at 25-40° C., and wherein the exposure occurs for a duration of 3-5 minutes.

6. The method of claim 1, wherein forming the mask further comprises depositing a water-soluble mask layer over the substrate and wherein removing the mask comprises a water rinse.

7. The method of claim 6, wherein the water-soluble mask layer comprises PVA.

8. The method of claim 7, wherein forming the mask further comprises depositing a multi-layered mask comprising the water-soluble mask layer as a base coat and a non-water-soluble mask layer as an overcoat on top of the base coat.

9. The method of claim 8, wherein the metal pumps or pads have a mask residue after mask removal, and wherein exposing the metal bumps or pads on a surface of the diced substrate to the inorganic acid solution removes the mask residue from the metal bumps or pads.

10. The method of claim 1, wherein patterning the mask further comprises direct writing a pattern with a femtosecond laser having a wavelength less than or equal to 540 nanometers and a laser pulse width less than or equal to 400 femtoseconds.

11. A method of dicing a semiconductor wafer comprising a plurality of integrated circuits (ICs), the method comprising:
forming a mask over the semiconductor wafer covering and protecting the ICs, the ICs including metal bumps or pads;
patterning the mask with a laser scribing process to provide a patterned mask with gaps, exposing regions of the semiconductor wafer between the ICs;
plasma etching the semiconductor wafer through the gaps in the patterned mask to singulate the ICs;
removing the mask to expose the metal bumps or pads; and
performing an inorganic acid wash of the exposed metal bumps or pads.

12. The method of claim 11, wherein the inorganic acid wash comprises exposing the semiconductor wafer to at least one of HCl and H₃PO₄.

13. The method of claim 12, wherein the inorganic acid wash comprises exposing the semiconductor wafer to HCl with 0.2-0.6 normality at 25-40° C. for a duration of 3-5 minutes.

14. The method of claim 12, wherein the inorganic acid wash comprises exposing the semiconductor wafer to H₃PO₄ with 2-6 normality at 25-40° C. for a duration of 3-5 minutes.

15. The method of claim 12, wherein the inorganic acid wash comprises exposing the semiconductor wafer to a mixture of 0.2-0.6 normal HCl with 2-6 normal H₃PO₄ at 25-40° C. for a duration of 3-5 minutes.

16. The method of claim 11, wherein the exposed metal bumps or pads have a mask residue after mask removal, and wherein performing the inorganic acid wash removes the mask residue from the exposed metal bumps or pads.

17. A system for dicing a substrate comprising a plurality of ICs, the system comprising:
a laser scribe module to pattern a mask and expose regions of the substrate between the ICs, the ICs including metal bumps or pads;
a plasma etch module physically coupled to the laser scribe module to plasma etch the substrate to singulate the ICs;
a wet clean station coupled to the plasma etch module, the wet clean station configured to remove the mask and to perform an inorganic acid wash of the metal bumps or pads; and
a robotic transfer chamber to transfer a laser scribed substrate from the laser scribe module to the plasma etch module and from the plasma etch module to the wet clean station.

18. The system of claim 17, wherein the laser scribe module comprises a femtosecond laser having a wavelength less than or equal to 540 nanometers and a pulse width of less than or equal to 400 femtoseconds.

19. The system of claim 17, wherein the plasma etch module is coupled to an SF₆ source and at least one of a C₄F₈ source, a CF₄ source, and a C₄F₆ source.

20. The system of claim 17, wherein the inorganic acid wash performed by the wet clean station comprises contacting the metal bumps or pads with at least one of HCl and H₃PO₄ to remove a residue from the metal bumps or pads.
